(19) United States
(12) Patent Application Publication
(10) Pub. No.: US 2026/0266923 A1
(43) Pub. Date: Sep. 10, 2026

(54) COIL-CALIBRATED MAGNETIC SENSOR

(71) Applicant: Allegro MicroSystems, LLC, Manchester, NH (US)

(72) Inventors: Tyler Daigle, Scarborough, ME (US); Steven Daubert, Bedford, NH (US); Srujan Shivanakere, Nashua, NH (US); Mathew Drouin, Manchester, NH (US)

(73) Assignee: Allegro MicroSystems, LLC, Manchester, NH (US)

(21) Appl. No.: 19/073,513

(22) Filed: Mar. 7, 2025

(51) Int. Cl. G01R 33/00; G01R 15/20; G01R 19/00; G01R 33/07

(52) U.S. Cl. CPC G01R 33/0017; G01R 15/202; G01R 19/0092; G01R 33/07

(57) ABSTRACT

A sensor, including: a first sensing element and a first calibration coil that is disposed adjacent to the first sensing element, the first sensing element being configured to generate a first signal at least in response to a primary magnetic field and a first calibration magnetic field that is generated by the first calibration coil; a second sensing element and a second calibration coil that is disposed adjacent to the second sensing element, the second sensing element being configured to generate a second signal at least in response to the primary magnetic field and a second calibration magnetic field that is generated by the second calibration coil; and one or more first summation elements that are configured to: (i) generate a calibration signal based on a difference between the first signal and the second signal by subtracting the difference from a reference signal.

### BACKGROUND

As is known, sensors are used to perform various functions in a variety of applications. Some sensors include one or more electromagnetic flux sensing elements, such as a Hall effect element, a magnetoresistive element, or a receiving coil to sense an electromagnetic flux associated with a quantity that is desired to be monitored. Sensor integrated circuits are widely used in automobile control systems and other safety-critical applications. There are a variety of specifications that set forth requirements related to permissible sensor quality levels, failure rates, and overall functional safety.

### SUMMARY

According to aspects of the disclosure, a sensor is provided, comprising: a first sensing element and a first calibration coil that is disposed adjacent to the first sensing element, the first sensing element being configured to generate a first signal at least in response to a primary magnetic field and a first calibration magnetic field that is generated by the first calibration coil; a second sensing element and a second calibration coil that is disposed adjacent to the second sensing element, the second sensing element being configured to generate a second signal at least in response to the primary magnetic field and a second calibration magnetic field that is generated by the second calibration coil; and one or more first summation elements that are configured to: (i) generate a calibration signal based on a difference between the first signal and the second signal by subtracting the difference from a reference signal and (ii) adjust respective biases of the first sensing element and the second sensing element based on the calibration signal, wherein the first calibration magnetic field and the second calibration magnetic field have opposite directions, wherein the primary magnetic field has a same direction at respective locations of the first sensing element and the second sensing element, and wherein adjusting the biases of the first sensing element and the second sensing element causes respective outputs of the first sensing element and the second sensing element to have a first gain that matches a second gain of the reference signal.

According to aspects of the disclosure, a sensor is provided, comprising: a first sensing element and a first calibration coil that is disposed adjacent to the first sensing element, the first sensing element being configured to generate a first signal at least in response to a primary magnetic field and a first calibration magnetic field that is generated by the first calibration coil; a second sensing element and a second calibration coil that is disposed adjacent to the second sensing element, the second sensing element being configured to generate a second signal at least in response to the primary magnetic field and a second calibration magnetic field that is generated by the second calibration coil; a first modulator that is configured to modulate a signal used to drive the first calibration coil and the second calibration coil based on a signal M; a first summation element that is configured to add the second signal to the first signal to at least in part generate a third signal that is indicative of a sum of the first signal and the second signal; and a feedback circuit that is configured to execute a correlation function that correlates the signal M with the signal used to drive the first calibration coil and adjust a bias of the first sensing element and the second sensing element based on a value of the correlation function, wherein the first calibration magnetic field and the second calibration magnetic field have a same direction, and wherein the primary magnetic field has opposite directions at respective locations of the first sensing element and the second sensing element.

According to aspects of the disclosure, a sensor is provided, comprising: a first sensing element and a first calibration coil that is disposed adjacent to the first sensing element, the first sensing element being configured to generate a first signal at least in response to a primary magnetic field and a first calibration magnetic field that is generated by the first calibration coil; a second sensing element and a second calibration coil that is disposed adjacent to the second sensing element, the second sensing element being configured to generate a second signal at least in response to the primary magnetic field and a second calibration magnetic field that is generated by the second calibration coil; a first modulator that is configured to modulate a signal used to drive the first calibration coil and the second calibration coil based on a signal M; a first summation element that is configured to subtract the second signal from the first signal to at least in part generate a third signal, the third signal being indicative of a difference between the first signal and the second signal; and a feedback circuit that is configured to execute a correlation function that correlates the signal M with the signal used to drive the first calibration coil and adjust a gain of the first signal and the second signal based on a value of the correlation function, wherein the first calibration magnetic field and the second calibration magnetic field have different directions, and wherein the primary magnetic field has opposite directions at respective locations of the first sensing element and the second sensing element.

### BRIEF DESCRIPTION OF THE DRAWINGS

The foregoing features may be more fully understood from the following description of the drawings in which:

FIG. 1A is a diagram of an example of a sensor, according to aspects of the disclosure;

FIG. 1B is a diagram of an example of a sensor, according to aspects of the disclosure;

FIG. 1C is a graph illustrating aspects of the operation of the sensor of FIG. 1B, according to aspects of the disclosure;

FIG. 1D is a diagram of an example of a sensor, according to aspects of the disclosure;

FIG. 2 is a diagram of an example of a sensor, according to aspects of the disclosure;

FIG. 3 is a diagram of an example of a sensor, according to aspects of the disclosure; and

FIG. 4 is a diagram of an example of a sensor, according to aspects of the disclosure.

### DETAILED DESCRIPTION

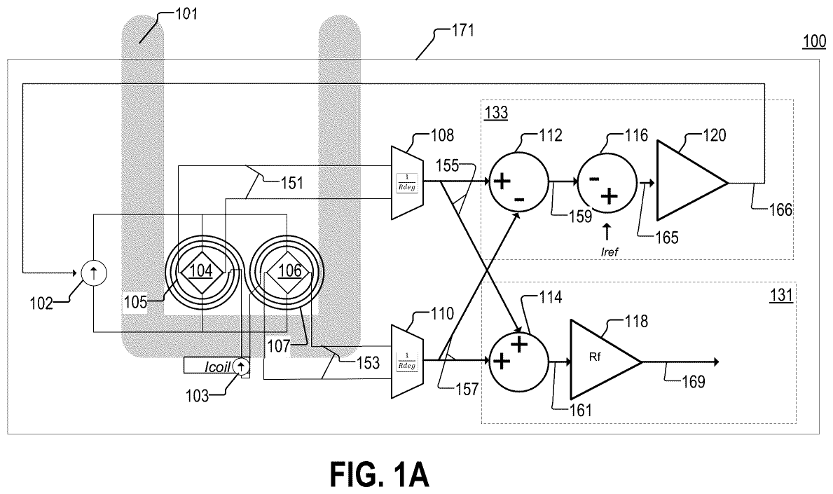

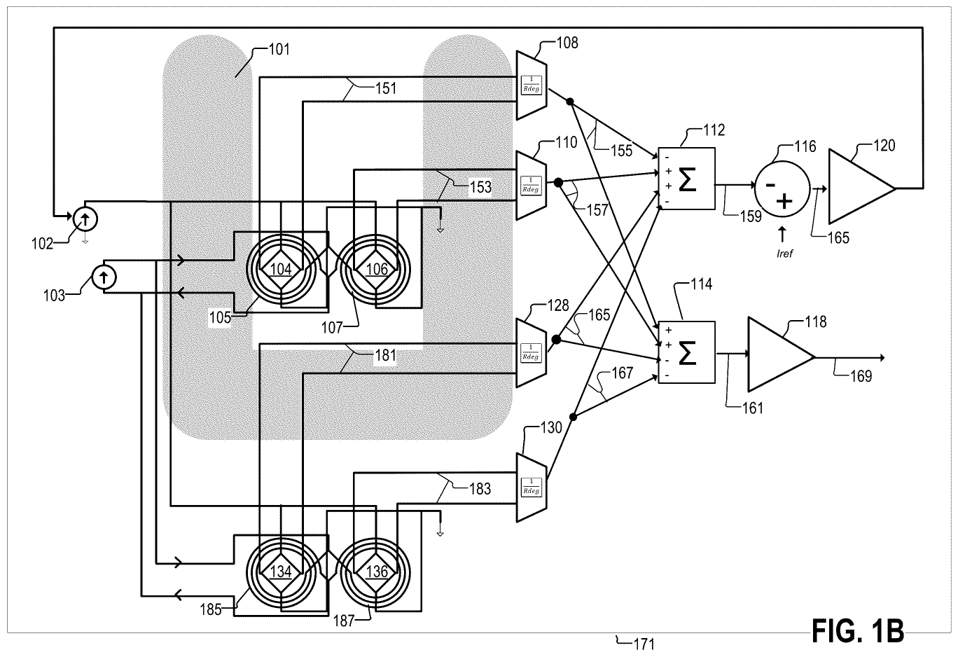

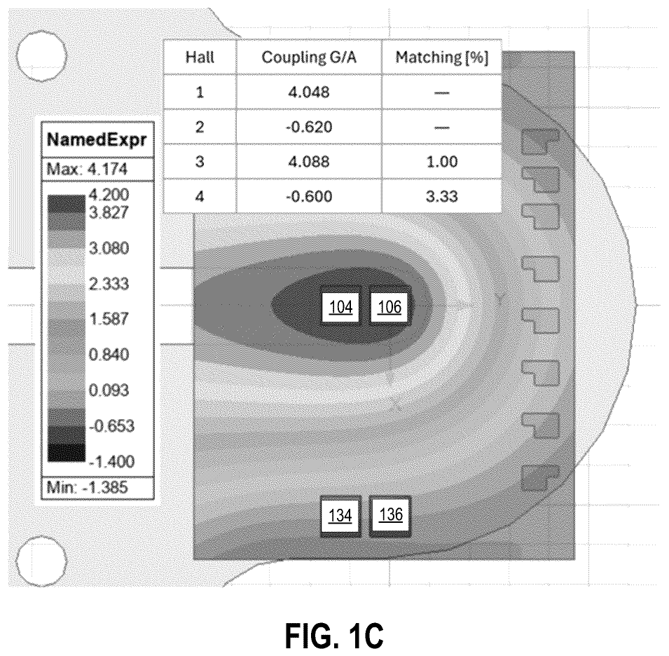

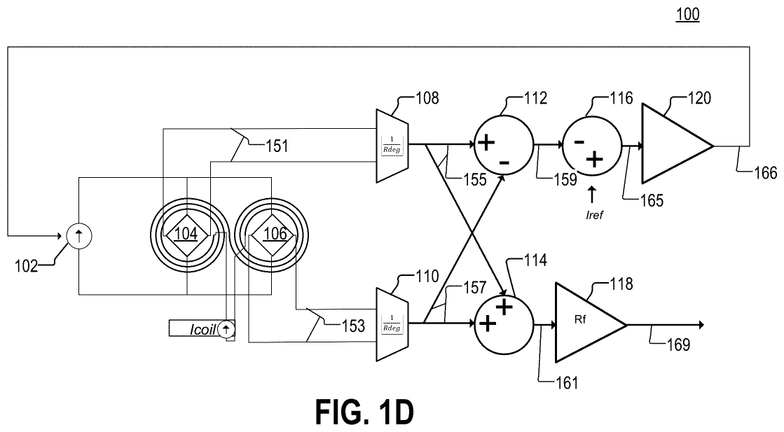

FIG. 1A is a diagram of an example of a sensor 100, according to aspects of the disclosure. In the example of FIG. 1A, sensor 100 includes a conductor 101 and a substrate 171. Current sources 102 and 103, calibration coils 105 and 107, Hall elements 104 and 106, trans-conductors 108 and 110, summation elements 112, 114, and 116 and amplifiers 118 and 120 may all be formed on the substrate 171. According to the present example, sensor 100 is a current sensor that is configured to measure the level of electrical current through the conductor 101. According to the present example, conductor 101 is integrated into the packaging of sensor 100; however, alternative implementations are possible in which conductor 101 is provided separately from sensor 100.

According to the present example, conductor 101 is U-shaped. Calibration coils 105 and 107 are positioned directly above or below the interior of the U-shape, as depicted. Calibration coils 105 and 107 may be implemented as conductive traces that are formed on the substrate 171. The substrate 171 may be a silicon substrate and/or any other suitable type of substrate that is customarily used in the manufacturing of semiconductor devices. The trans-conductors 108 and 110, according to the present example, are Gilbert cells; however, the present disclosure is not limited to using any specific type of trans-conductor.

Sensor 100 may include a feedback path 133 and a signal path 131. The feedback path 133 may include summation elements 112 and 116 and amplifier 120. Signal path 131 may include summation element 114 and amplifier 118. The purpose of signal path 131 is to, at least in part, generate a signal that is indicative of the level of electrical current flowing through conductor 101. The purpose of the feedback path is to counteract the effects of aging or environmental conditions, such as temperature and stress, on the sensitivity of Hall elements 104 and 106. As is discussed further below, in the example of FIG. 1A, feedback path 133 may be used to adjust the gain of signal path 131. Feedback path 133 may used to adjust the gain of signal path 131 by adjusting the bias of the Hall elements 104 and 106. Throughout this disclosure, the term “adjusting the bias of a sensing element” shall refer to changing (e.g., increasing or decreasing) the voltage or current used to drive the sensing element.

A more detailed description of the operation of feedback path 133 is now provided. Current source 103 may generate a constant coil current Icoil, which drives calibration coils 105 and 107. Calibration coils 105 and 107 may generate fixed calibration magnetic fields that are independent of temperature and stress based on the coil current. The calibration magnetic field generated by calibration coil 105 may be positive, causing Hall element 104 to generate a positive voltage (signal 151). The calibration magnetic field generated by calibration coil 107 may be negative, causing Hall element 106 to generate a negative voltage (e.g., signal 153). The positive voltage (signal 151) may be converted to current (e.g., signal 155) by trans-conductor 108. The negative voltage (signal 153) may be converted to current (e.g., signal 157) by trans-conductor 110. The current generated by trans-conductor 110 (e.g.signal 157) may be subtracted by summation element 112 from the current generated by trans-conductor 108 (e.g.signal 155) to produce a difference signal 159. Difference signal 159 may be subtracted from a reference signal Iref by summation element 115 to produce a signal 165, after which signal 165 may be converted to a voltage by amplifier 120 to produce a calibration voltage (e.g., calibration signal 166).

The reference signal Iref represents a baseline that ideally remains unaffected by aging or environmental conditions like stress or temperature. Subtracting signal Iref from signal 159 is advantageous because it registers variations in signal 159 that are caused by aging or environmental conditions, such as temperature or stress. In this context, the calibration signals 165 and/or 166, which represent the difference, indicate how the sensitivity of Hall elements 104 and 106 is influenced by aging or environmental conditions. Applying signal 166 to current source 102 can either: (i) increase the power supply current/voltage of Hall elements 104 and 106 when their sensitivity decreases due to aging or environmental conditions or (ii) decrease the power supply current/voltage of Hall elements 104 and 106 when their sensitivity is increased by aging or environmental conditions.

In one example, reference signal Iref may be produced by external circuitry and received at one or more input pins (not shown) of sensor 100. Alternatively, signal Iref may be produced by electronic circuitry formed on the substrate 171. The electronic circuitry may be formed of electronic components that are less susceptible than Hall elements 104 and 106 to the effects of aging or environmental conditions, due to their size or materials used, or for other reasons. In one example, the same resistor Rref and possibly the same voltage source Vref (e.g., see equation 3 below) may be used to generate both the coil current Icoil and the reference signal Iref. In such scenarios, the calibrated sensitivity of Hall elements 104 and 106 would be proportional to Rref and independent of Vref.

The calibration voltage (e.g., signal 166) is utilized to adjust the gain of the signal path 131 of sensor 100. The gain adjustment is performed in order to compensate for the effects of temperature, stress, and/or other environmental conditions on the sensitivity of Hall elements 104 and 106. In this example, the calibration voltage is applied to adjust the bias of Hall elements 104 and 106. Specifically, current source 102 functions as a variable current source, with the calibration voltage (e.g., signal 166) applied to a control terminal of current source 102. This sets the level of electrical current that is supplied by current source 102 to drive Hall elements 104 and 106. Although in the present example, the reference voltage (e.g., signal 166) is used to adjust the bias of Hall elements 104 and 106, in alternative implementations, the reference voltage may be used to adjust the trans-conductance of trans-conductors 108 and 110 or the front-end gain of sensor 100. For example, the reference voltage (e.g., signal 166) may be used to adjust the gain of amplifiers 118 and 122. According to the present example, signal 166 is generated in the analog domain. However, alternative implementations are possible in which signal 166 is at least in part generated in the digital domain.

In another example, the feedback path 133 may be implemented by using a summing or instrumentation amplifier instead of the trans-conductors 108 and 110. This amplifier may be used to: (i) subtract the Hall voltages from one another (e.g., subtract signal 157 from signal 155), and (ii) add the resulting difference to a fixed voltage. The resulting sum, which is the output of the summing or instrumentation amplifier, may then be fed into a high-gain stage to generate the calibration voltage (e.g., signal 166).

The operation of the signal path 131 is now described in further detail. The current generated by trans-conductor 108 (e.g., signal 155) may be added by summation element 114 to the current generated by trans-conductor 110 (e.g., signal 157) to produce a signal 161. Signal 161 may be amplified by amplifier 118 to produce a signal 169. In this example, signal 169 is the output signal of sensor 100 and it is indicative of the level of electrical current through conductor 101. In some implementations, sensor 100 may include circuitry that is configured to perform further processing on signal 169 before signal 169 is output from sensor 100 to external circuitry.

The operation of sensor 100 without the calibration performed by calibration coils 105 and 107 may be described by equation 1 below:

$$\frac{{V}_{o}}{{I}_{IN}} = {M}_{H} ( \frac{Vref}{Ref} ) {C}_{F} {S}_{H} \qquad ( 1 )$$

Where Vo is the value of signal 169 (e.g., the output voltage of signal path 131), I_{IN} is the level of the electrical current that is flowing through conductor 101, M_{H} is a scaling factor, Vref is a bandgap voltage reference, Rref is a fixed resistance (or a fixed resistor), S_{H} is the sensitivity of Hall elements 104 and 106, and C_{F} is a coupling factor that describes the magnetic coupling between Hall elements 104 and 106 and conductor 101.

The operation of sensor 100, while calibration coils 105 and 107 are used to perform calibration, may described by equations 2 and 3 below:

$$\frac{{V}_{o}}{{I}_{IN}} = {N}_{H} {R}_{ref} ( \frac{{C}_{F}}{{C}_{cf}} ) \qquad ( 2 )$$

$$Icoil = \frac{Vref}{Rref} \qquad ( 3 )$$

Where Vo is the value of signal 169 (e.g., the output voltage of the signal path of sensor 100), I_{IN} is the level of the electrical current that is flowing through conductor 101, N_{H} is a scaling factor, Vref is a bandgap reference voltage, Rref is a fixed resistance, Icoil is the electrical current used to drive calibration coils 105 and 107, and C_{F} is a coupling factor that describes the magnetic coupling between Hall elements 104 and 106 and conductor 101, C_{cf} is a coupling factor that describes the magnetic coupling between calibration coils 105 and 107 and Hall elements 104 and 106.

FIG. 1B shows another architecture for sensor 100. This architecture differs from that shown in FIG. 1A by incorporating Hall elements 134 and 136, calibration coils 185 and 187 and trans-conductors 128 and 130. Additionally, the summation elements 112 and 114 are 4-way summation elements in the example of FIG. 1B, whereas in the example of FIG. 1A they are 2-way summation elements. Hall elements 134 and 136 are formed on substrate 171. Hall elements 134 and 136 are formed on the opposite side of conductor 101 from Hall elements 104 and 106. Calibration coils 185 and 187 may also be formed on substrate 171. Calibration coil 185 may be configured to surround Hall element 134, and calibration coil 187 may be configured to surround Hall element 136. In the example of FIG. 1B, Hall elements 134 and 136 help mitigate the effects of stray magnetic fields, and calibration coils 185 and 187 counteract the effects of environmental factors, such as temperature and stress, on the sensitivity of Hall elements 134 and 136.

Calibration coils 185 and 187 may be energized by electrical current generated by current source 103. Calibration coils 185 and 187 may generate fixed calibration magnetic fields that are independent of temperature and stress in response to the coil current. The calibration magnetic field generated by calibration coil 185 may be positive, causing Hall element 134 to generate a positive voltage (signal 181). Conversely, the calibration magnetic field generated by calibration coil 187 may be negative, causing Hall element 136 to generate a negative voltage (e.g., signal 183). Signals 151, 153, 181, and 183 may be converted to current by trans-conductors 108, 110 128, and 130, and the converted signals may be subsequently combined by summation elements 112 and 114. Specifically, summation element 112 may generate signal 159 in accordance with equation 4 below, and summation element 114 may generate signal 161 based on equation 5 below:

$${S}_{159} = - {S}_{155} + {S}_{157} + {S}_{165} - {S}_{167} \qquad ( 4 )$$

$${S}_{161} = + {S}_{155} + {S}_{157} - {S}_{165} - {S}_{167} \qquad ( 5 )$$

Where signal S₁₅₉ is the value of signal 159, S₁₆₁ is the value of signal 161, Siss is the value of signal 155, S₁₅₇ is the value of signal 157, S₁₆₅ is the value of signal 165, and S₁₆₇ is the value of signal 167.

FIG. 1C is a heat map showing the result of a magnetic simulation for the configuration of sensor 100 depicted in FIG. 1B. The bands in the heatmap show the strength of the magnetic field generated by conductor 101 at the location of each of Hall elements 104, 106, 134, and 136. Additionally, FIG. 1C illustrates the magnetic coupling coefficients between conductor 101 and each of Hall elements 104, 106, 134, and 136. FIG. 1C illustrates that the magnetic coupling coefficient of Hall element 104 closely matches the magnetic coupling coefficient of Hall element 106, while the magnetic coupling coefficient of Hall element 134 closely matches the magnetic coupling coefficient of Hall element 136. This congruence between the magnetic coupling coefficients is advantageous as it results in improved sensitivity of sensor 100. Typically, a mismatch would result in a non-linearity error. The non-linearity error can be corrected by modulating signal 166.

FIG. 1D shows another possible architecture of sensor 100. In the example of FIG. 1D, conductor 101 is omitted, illustrating that sensor 100 can function as a different type of magnetic field sensor, such as a position sensor. Apart from this difference, the architecture shown in FIG. 1D is identical to the architecture shown in FIG. 1A, underscoring that the concepts and ideas discussed with respect to FIG. 1A are not limited to current sensors only, and they can be used to improve the operation of any possible type of magnetic field sensor. In some respects, the architecture illustrated in the example of FIGS. 1A-4 is advantageous because it does not require extra switching to be performed on the calibration coils 105 and 107, which simplifies operation and reduces switching noise.

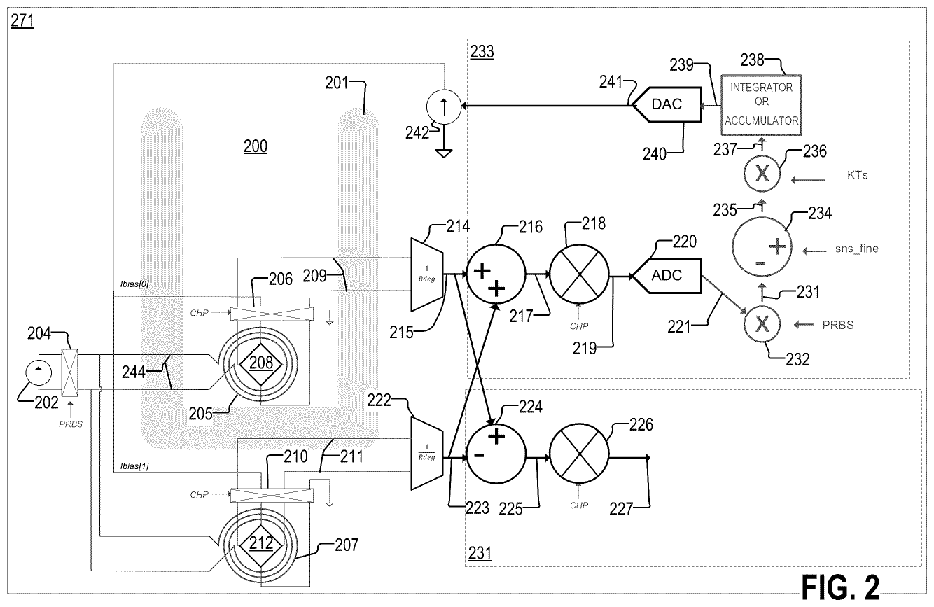

FIG. 2 is a diagram of an example of a sensor 200, according to aspects of the disclosure. Sensor 200 may include a conductor 201 and a substrate 271. On the substrate 271, various components may be formed, such as current sources 202 and 242, Hall elements 208 and 212, calibration coils 205 and 207, trans-conductors 214 and 222, modulators 204, 206 and 210, summation elements 216 and 224, demodulators 218 and 226, an analog-to-digital converter (ADC) 220, an integrator 238, a digital-to-analog converter (DAC) 240, a multiplier 232, a summation element 234, a multiplier 236. In this example, conductor 201 is integrated within the packaging of sensor 200; however, alternative implementations are possible where conductor 201 is provided separately from sensor 200. According to the present example, sensor 200 is a current sensor configured to measure the level of electrical current through conductor 201. Those of ordinary skill in the art will readily recognize that a multiplier performs the same function as a digital demodulator and/or digital modulator. However, for the sake of clarity, the term “multiplier” is used in the examples presented throughout the disclosure.

Sensor 200 may include a feedback path 233 and a signal path 231. Signal path 231 may include summation element 224 and demodulator 226. The purpose of signal path 231 is to, at least in part, generate a signal that is indicative of the level of electrical current flowing through conductor 201 (e.g., signal 227). The feedback path 233 may include summation element 216, demodulator 218, ADC 220, multiplier 232, summation element 234, multiplier 236, integrator 238, and DAC 240. The feedback path's purpose is to counteract the effects of aging and environmental factors like temperature and stress, on the sensitivity of Hall elements 208 and 212. In the example depicted in FIG. 2, feedback path 233 adjusts the gain of signal path 231.

Hall elements 208 and 212 may be positioned on opposite sides of conductor 201. Conductor 201 may generate a magnetic field (hereinafter “primary magnetic field”) when electrical current flows through it. The primary magnetic field may have one direction at the location of Hall element 208 and an opposite direction at the location of Hall element 212. Calibration coils 205 and 207 may be arranged to generate magnetic fields (hereinafter “calibration magnetic fields”) that have the same direction at both Hall element locations. The sensitivities of Hall elements 208 and 212 may be matched, and Hall elements 208 and 212 may have the same magnetic coupling to calibration coils 207 and 205, which allows the calibration magnetic fields to be canceled out from signal path 231 by summation element 224. In addition, the magnetic coupling between Hall element 208 and conductor 201 may be matched to the magnetic coupling between Hall element 212 and conductor 201, which allows the primary magnetic field to be canceled out by summation element 216.

Calibration coil 205 may be configured to surround Hall element 208 and calibration coil 207 may be arranged to surround Hall element 212. Calibration coils 205 and 207 may be implemented as conductive traces on substrate 271. Calibration coils 205 and 207 may be energized with a signal that is produced by current source 202 and modulated by modulator 204. The modulation is performed based on a pseudo-random bit string (PRBS). The PRBS includes an equal number of is and Os that appear in a nearly random order. Commonly the sequence is generated using a linear-feedback shift register (LFSR) where a shift register of length n generates a pseudo-random sequence of 2ⁿ−1. The PRBS is encoded in analog as a waveform with amplitudes ±Icoil, where ‘1’ is encoded as +Icoil and ‘0’ is encoded as a −Icoil before being fed to modulator 204. In this example, Icoil is the level of the electrical current used to drive the calibration coils 105 and 107.

The operation of current source 242 is now described in further detail. Current source 242 may be used to power Hall elements 208 and 212. Current source 242 may be configured to operate as a variable current source. The level of the electrical current that is supplied by current source 242 to Hall elements 208 and 212 may be set by a signal 241. In this example, signal 241 is the output of feedback path 233. The application of signal 241 to current source 242 allows the sensitivity of Hall elements 208 and 212 to be increased or decreased in a way that counteracts the effects, on the sensitivity of Hall elements 208 and 212, of aging or environmental conditions like temperature and stress.

The operation of Hall elements 208 and 212 is now described in more detail. The output of Hall element 208 may be modulated at a chopping frequency CHP by modulator 206 to produce a voltage signal 209, which is subsequently converted into a current signal 215 by trans-conductor 214. The output of Hall element 212 may be modulated at the chopping frequency CHP by modulator 210 to produce a voltage signal 211 which is subsequently converted into a current signal 223 by trans-conductor 222. In the present example, modulators 206 and 210 are used to perform frequency chopping on the output of Hall elements 208 and 212, which is a well-known technique for removing offset.

The operation of signal path 231 is now described in further detail. As illustrated, summation element 224 may subtract signal 223 from signal 215 to generate a signal 225. And demodulator 226 may demodulate signal 225 at the chopping frequency CHP to produce a signal 227. In the present example, signal 227 is indicative of the level of electrical current through conductor 201. Signal 227 may be either output from sensor 200 to external circuitry or further processed within sensor 200 by other components that are part of signal path 231 (not shown).

The operation of feedback path 233 is now described in further detail. Summation element 216 may add signals 215 and 223 to produce a signal 217. Demodulator 218 may demodulate signal 217 at the chopping frequency CHP to produce a signal 219. ADC 220 may digitize signal 219 to produce a signal 221. Multiplier 232 may demodulate signal 221 based on signal PRBS. Summation element 234 may add to signal 231 a reference signal sns_fine to produce a signal 235. Multiplier 236 may multiply signal 235 by adjustment coefficients KTs to produce a signal 237. Integrator 238 may integrate signal 237 to produce a signal 239. DAC 240 may convert signal 239 to analog signal 241.

In some respects, multiplier 236 and integrator 238 may be configured to implement a correlation function. The correlation function may be described by equation 6 below:

$$acc [ n ] = {\sum }_{i = 1}^{i = n} KTs \cdot ( adc [ i ] \cdot PRBS [ i ] - sns\_fine ) \qquad ( 6 )$$

where: KTs is a plurality of adjustment coefficients KT, n represents cycle number (synchronous to PRBS), adc[n]is ADC output (i.e., the value of signal 221) at cycle n, PRBS[n]is the value of the PRBS signal at cycle n, such that PRBS[n]c {+1, −1}, sns_fine is target sensitivity level (and the value of signal sns_fine in FIG. 2), and acc[n]is accumulated error at cycle n. In this example, acc[n]is the value of signal 239 and sns_fine is a constant value corresponding to the desired amplitude of the PBRS signal at multiplier 232. In some respects, the ADC output (i.e., signal 221) represents the calibration signal that is provided to the coils by modulator 204 after signal path gain through the transconductors 214 and 222, the summation stage 216, and the ADC 220. The output of modulator 204 is denoted as signal 244 in FIG. 2. KTs may be a bit string where each bit is the value of a different coefficient KT. The term “cycle” as used herein refers to each iteration in which the entire digital feedback loop (i.e., signal path 233) is updated. In some implementations, the signals that are updated in each cycle include PBRS, 221, 231 235, 237, and 239. In some implementations, the transition between cycles can be driven by the rising (or falling) edge of a clock signal, etc.

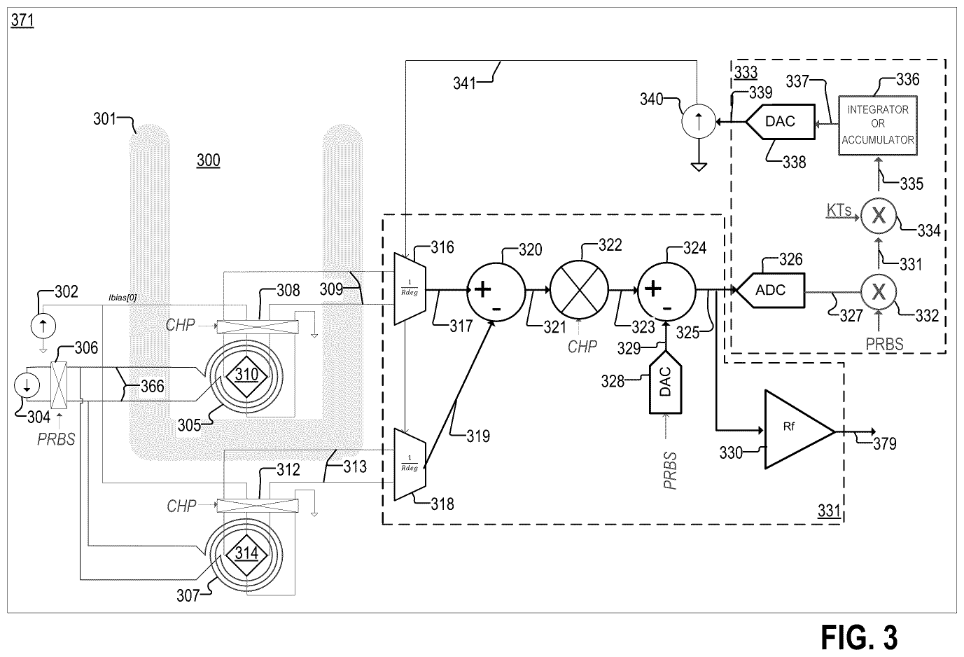

FIG. 3 is a diagram of an example of a sensor 300, according to aspects of the disclosure. In this example, sensor 300 includes a conductor 301 and a substrate 371. Formed on substrate 371 are current sources 302, 304, and 340, modulators 306, 308, and 312, Hall elements 310 and 314, calibration coils 305 and 307, trans-conductors 316 and 318, summation elements 320 and 324, a demodulator 322, a DAC 328, an ADC 326, an amplifier 330, a multiplier 332, a multiplier 334, and an integrator 336. In the present example, conductor 301 is integrated into the packaging of sensor 300; however, alternative implementations are possible in which conductor 301 is provided separately from sensor 300. According to the present example, sensor 300 is a current sensor that is configured to measure the level of electrical current through conductor 301.

Sensor 300 may include a feedback path 333 and a signal path 331. Signal path 331 may include trans-conductors 316 and 318, summation elements 320 and 324, demodulator 322, DAC 328, and amplifier 330. Feedback path 333 may include multiplier 332, multiplier 334, integrator 336, and DAC 338. The purpose of signal path 331 may be to, at least in part, generate a signal that indicates the level of electrical current flowing through conductor 301. In contrast, feedback path 333 aims to adjust the gain of signal path 331 in order to counteract the effects of aging and environmental conditions, like temperature or stress, on the sensitivity of Hall elements 310 and 314. Feedback path 333 may be configured to generate a signal 341, which is used to adjust the transconductance of trans-conductors 316 and 318. However, in alternative implementations, the output of signal path 331 may be used to change the gain of amplifier 330 and/or any other component of signal path 331. Although, in the example of FIG. 3, feedback path 333 is implemented in the digital domain, alternative implementations are possible in which feedback path 333 is implemented in the analog domain.

Similar to sensor 200, sensor 300 also uses differential Hall elements—one inside the loop defined by conductor 301 and one outside of the loop. However, unlike sensor 200, sensor 300 uses calibration coils that generate calibration magnetic fields with opposite directions. As a result of this arrangement, a single pipeline may be used to measure the magnetic field generated by conductor 301 and the magnetic fields generated by calibration coils 307 and 305.

Conductor 301 may generate a magnetic field (hereinafter “primary magnetic field”) as a result of electrical current flowing through conductor 301. The primary magnetic field may have one direction at the location of Hall element 310 and a different (opposite) direction at the location of Hall element 314. The calibration coils 305 and 307 may produce magnetic fields (calibration magnetic fields) that also have opposite directions.

To isolate the main signal (generated in response to the primary magnetic field) from the test signal (generated in response to the calibration magnetic fields), fixed frequency or Pseudo-Random Binary Sequence (PRBS) modulation can be utilized. This would result in a fixed tone or PRBS noise appearing in sensing path 331. The test signal, while relatively small (in the −60 dBFs range), may be large enough to noticeably affect the output noise spectrum. To remove the test signal from the output of sensing path 331, it is necessary to subtract, in the sensing path 331, a scaled replica of the fixed frequency or PRBS signal 329. The scale factor of the replica signal 329 is used to set the desired signal path gain through the Hall elements 310 and 314, transconductors 316 and 318, and modulators 306, 308, 312, and 322. The feedback path 333 will adjust the gain of the signal path 331 via signal 341 such that the PRBS signal that traveled through signal path 331 (or ADC 328 and summation unit 324) and the replica PRBS signal 329 are the same amplitude. In the example of FIG. 3, the offset injection may be performed at summation element 324 while the initial modulation of the test signal may be performed at modulator 306. Signal path 331 subtracts the modulated offset signal from the modulated test signal and main signal to produce the modulated, corrected calibration signal plus main signal, which is signal 325. When the feedback path 333 has stabilized, the modulated and corrected calibration signal will be close to 0V, so signal 325 would mainly contain the main input signal. Amplifier 330 is used to buffer and scale the signal 325 to produce output signal 379.

Feedback path 333 derives the compensation signal 341 by correlating the signal 327 with the PRBS signal using multiplier 332. The component of signal 327 which originated at modulator 306 will correlate with the PRBS signal at multiplier 332. Following a multiplication by the scale factors KTs and averaging in the integrator 336, the signal 337 will represent any “error signal” of the calibration. This will be converted to an analog signal 339, and will adjust the path gain of the transconductors 316 and 318 until the residual PRBS signal at 325 is very close to 0. In the example of FIG. 3, signal 331 is the signal that is produced by the demodulation and filtering stage. Signal path 331 then evaluates a correlation function based on signal 331. The correlation function may be evaluated by using modulator 334 and integrator 336. In the example of FIG. 3, the value of the correlation function is signal 337. The compensation signal 341 may be generated by converting signal 337 to an analog signal 339 and applying signal 339 to the control terminal of current source 340 to adjust the level of compensation signal 341. Applying the correlation function averages the main input signal to zero. As used herein, the term “main input” or “main signal” refer to the signal that is generated by Hall elements 308 and 312 in response to the primary magnetic field. As noted above, the primary magnetic field is generated as a result of electrical current flowing through conductor 301. In this regard, adjusting the gain of signal path 331 based on signal 341 forces the amplitude of the PRBS signal at modulator 306 to match the amplitude of signal 337 at DAC 338, which has the effect of masking any variations in the sensitivity of Hall elements 310 and 314 that might result from aging or the action of environmental conditions.

The operation of calibration coils 305 and 307 is now described in further detail. Calibration coil 305 may be arranged to surround Hall element 310, and calibration coil 307 may be arranged to surround Hall element 314. Calibration coils 305 and 307 are driven with a signal generated by current source 304 which is then modulated by modulator 306 based on the signal PRBS.

The operation of Hall elements 310 and 314 is now described in further detail. The output of Hall element 310 may be modulated by modulator 308 based on chopping frequency CHP to produce a voltage signal 309. The output of Hall element 314 may be modulated by modulator 312 based on the chopping frequency CHP to produce a voltage signal 313. In the present example, modulators 308 and 312 are used to perform frequency chopping on the output of Hall elements 310 and 314

The operation of signal path 331 is now described in further detail. Trans-conductor 316 may convert voltage signal 309 to a current signal 317. Trans-conductor 318 may convert signal 313 to a current signal 319. Summation element may subtract signal 319 from signal 317 to produce a signal 321. Demodulator 322 may demodulate signal 321 at the chopping frequency CHP to produce a signal 323. DAC 328 may convert the PRBS signal to an analog signal 329. Summation element 324 may subtract signal 329 from signal 323 to produce a signal 325. Amplifier 330 may amplify signal 325 to produce signal 379. In the present example, signal 379 is indicative of the level of electrical current through conductor 301. Signal 379 may be either output from sensor 300 to external circuitry or further processed within sensor 300 by additional components in signal path 331 (not shown).

The operation of feedback path 333 is now described in further detail. ADC 326 may digitize signal 325 to produce a signal 327. Multiplier 332 may multiply signal 327 by signal PRBS to produce a signal 331. Multiplier 334 may multiply signal 331 by coefficients KT to produce a signal 335. Integrator 336 may integrate signal 335 to produce a signal 337. DAC 338 may convert signal 337 to an analog signal 339. Signal 339 may be applied to the control terminal of current source 340. Current source 340 may be implemented as a variable current source. Current source 340 may output a signal 341, and the application of signal 339 to the control terminal of current source 340 may set the level of signal 341. As noted above, signal 341 may be used to adjust the transconductance of trans-conductors 316 and 318.

In some respects, multiplier 334 and integrator 336 may be configured to implement a correlation function. The correlation function may be described by equation 7 below:

$$acc [ n ] = {\sum }_{i = 1}^{i = n} KTs \cdot adc [ i ] \cdot PRBS [ i ] \qquad ( 7 )$$

where: KTs is a plurality of adjustment coefficients KT, n represents cycle number (synchronous to PRBS), adc[n]is ADC output (i.e., the value of signal 327), at cycle n, PRBS[n]is the value of the PRBS signal at cycle n, such that PRBS[n]⊂{+1, −1}, and acc[n]is accumulated error at cycle n. In this example, acc(n) is the value of signal 337 at cycle n. It should be noted that the sns_fine summation (shown in FIG. 2) is not present in FIG. 3 since the correction in FIG. 3 is done in the analog domain with DAC 328 and summation element 324. In some respects, the ADC output (i.e., signal 327) represents the calibration signal that is provided to the coils by modulator 306 after signal path gain through the transconductors 316 and 318, the summation stages 320 and 324, and the ADC 326. The output of modulator 306 is denoted as signal 366 in FIG. 3. KTs may be a bit string where each bit is the value of a different coefficient KT. The term “cycle” as used herein refers to each iteration in which the entire digital feedback loop (i.e., signal path 333) is updated. In some implementations, the signals that are updated in each cycle include PBRS, 327, 331 335, 337, and 339. In some implementations, the transition between cycles can be driven by the rising (or falling) edge of a clock signal, etc.

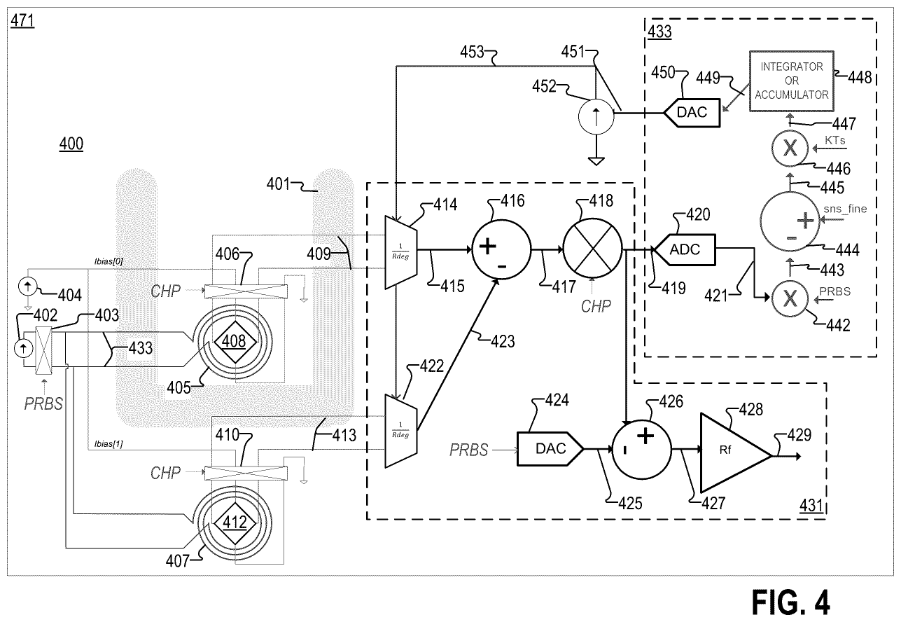

FIG. 4 is a diagram of an example of a sensor 400, according to aspects of the disclosure. In the example of FIG. 4, sensor 400 includes a conductor 401 and a substrate 471. Formed on substrate 471 are current sources 402, 404, and 452, modulators 403, 406, and 410, multipler 446, a multiplier 442 and a demodulator 418, calibration coils 405 and 407, Hall elements 408 and 412, trans-conductors 414 and 422, summation elements 416 and 426, DACs 424 and 450, an ADC 420, an amplifier 428, a summation element 444, and an integrator 448. According to the present example, conductor 401 is integrated into the packaging of sensor 400. However, alternative implementations are provided in which conductor 401 is provided separately from sensor 400. According to the present example, sensor 400 is a current sensor that is configured to measure the level of electrical current through conductor 401.

Sensor 400 may include a feedback path 433 and a signal path 431. Signal path 431 may include trans-conductors 414 and 422, summation element 416, demodulator 418, DAC 424, summation element 426, and amplifier 428. Feedback path 433 may include ADC 420, multiplier 442, summation element 444, multiplier 446, integrator 448, and DAC 450. The purpose of signal path 431 may be to, at least in part, generate a signal that is indicative of the level of electrical current flowing through conductor 401 (e.g., signal 429). The purpose of feedback path 433 may be to adjust the gain of signal path 431 in order to compensate for changes in the sensitivity of Hall elements 408 and 412, which result from aging or the action of environmental conditions, such as temperature or stress. In the example of FIG. 4, feedback path 433 may be configured to generate a signal 453 which is used to adjust the transconductance of trans-conductors 414 and 422. However, in alternative implementations, the output of signal path 431 may be used to adjust the gain of an amplifier that is coupled between the summation element 416 and ADC 420, and/or another similar component. Although, in the example of FIG. 4, feedback path 433 is implemented in the digital domain, alternative implementations are possible in which feedback path 433 is implemented in the analog domain.

Sensor 400 operates on the same principles as sensor 300. However, the difference is that the modulated test signal is subtracted by DAC 424 and summation element 426 at a later stage in the signal path. Feedback path 433 serves to force the amplitude of the PRBS signal at the input of ADC 420 to match the level defined by signal sns_fine, which is applied at summation element 444. Similar to sensor 300, integrator 448 and multiplier 446 implement a correlation function that averages any input signal to 0. The PRBS-modulated signal that is used to drive calibration coils 405 and 407 is correlated with the PRBS signal (in digital form), and feedback path 433 aims to match the amplitude of signal 419 to the amplitude of the PRBS signal level defined by sns_fine by adjusting the gain of trans-conductors 414-422. By ensuring that the full amplitude of the test signal is present at the input of ADC 420, the feedback path 433 converges more quickly to adjust the gain of sensing path 431 than sensor 300. This “matching” is done in the digital domain with summation element 444. When the feedback path 433 has stabilized, the average demodulated calibration signal 443 should be equal to signal sns_fine.

Conductor 401 may generate a magnetic field (hereinafter “primary magnetic field”) as a result of electrical current flowing through conductor 401. The primary magnetic field may have one direction at the location of Hall element 408 and a different (opposite) direction at the location of Hall element 412. The calibration coils 405 and 407 may produce magnetic fields (calibration magnetic fields) that also have opposite directions. Calibration coil 405 may be arranged to surround Hall element 408, and calibration coil 407 may be arranged to surround Hall element 412. Calibration coils 405 and 407 may be powered by a signal generated by current source 402 which is then modulated by modulator 403 based on the signal PRBS.

The operation of Hall elements 408 and 412 is now described in further detail. As illustrated, Hall elements 408 and 412 are powered by current source 404. The output of Hall element 408 may be modulated by modulator 406 based on chopping frequency CHP to produce a voltage signal 409. Similarly, the output of Hall element 412 may be modulated by modulator 410 based on the chopping frequency CHP to produce a voltage signal 413. In the present example, modulators 406 and 410 are used to perform frequency chopping on the output of Hall elements 408 and 412.

The operation of signal path 431 is now described in further detail. Trans-conductor 414 may convert voltage signal 409 to a current signal 415. Trans-conductor 422 may convert voltage signal 413 to a current signal 423. Summation element 416 may subtract signal 423 from signal 415 to produce a signal 417. Demodulator 418 may demodulate signal 417 at the chopping frequency CHP to produce a signal 419. DAC 424 may convert the PRBS signal to an analog signal 425. Summation element 426 may subtract signal 425 from signal 419 to produce a signal 427. Amplifier 428 may amplify signal 427 to produce a signal 429. In the present example, signal 429 is indicative of the level of electrical current through conductor 401. Signal 429 may be either output from sensor 400 to external circuitry or further processed within sensor 400 by additional components in signal path 431 (not shown).

The operation of feedback path 433 is now described in further detail. ADC 420 may digitize signal 419 to produce a signal 421. Multiplier 442 may multiply signal 421 by signal PRBS to produce a signal 443. Summation element 444 may subtract signal 443 from a signal sns_fine to produce a signal 445. Multiplier 446 may multiply signal 445 by coefficients KTs to produce a signal 447. Integrator 448 may integrate signal 447 to produce a signal 449. DAC 450 may convert signal 449 to an analog signal 451. Signal 451 may be applied to the control terminal of current source 452. Current source 452 may be implemented as a variable current source. Current source 452 may output a signal 453, and the application of signal 451 to the control terminal of current source 452 may set the level of signal 453. As illustrated in FIG. 4, signal 453 may be used to adjust the transconductance of trans-conductors 414 and 422.

In some respects, multiplier 446 and integrator 448 may be configured to implement a correlation function. The correlation function may be described by equation 8 below.

$$acc [ n ] = {\sum }_{i = 1}^{i = n} KTs \cdot ( adc [ i ] \cdot PRBS [ i ] - sns\_fine ) \qquad ( 8 )$$

where KTs is a plurality of adjustment coefficients KT, n represents cycle number (synchronous to PRBS), adc[n]is ADC output at cycle n (i.e., the value of signal 421 at cycle n), PRBS[n]is the value of the PRBS signal at cycle n, such that PRBS[n]⊂[+1, −1], sns_fine is a target sensitivity level, acc[n]is accumulated error at cycle n. In this example, acc[n]is the value of signal 449 and sns_fine is a constant value corresponding to the desired amplitude of the PBRS signal at 421. In some respects, the ADC output (i.e., signal 421) represents the calibration signal that is provided to the coils by modulator 403 after signal path gain through the transconductors 414 and 422, the summation stage 416, and the ADC 420. The output of modulator 403 is denoted as signal 433 in FIG. 4. KTs may be a bit string where each bit is the value of a different coefficient KT. The term “cycle” as used herein refers to each iteration in which the entire digital feedback loop (i.e., signal path 433) is updated. In some implementations, the signals that are updated in each cycle include PBRS, 421, 443, 445, 447, and 449. In some implementations, the transition between cycles can be driven by the rising (or falling) edge of a clock signal, etc.

In some implementations, the architectures shown in FIGS. 3-4 are advantageous because they require only two Hall elements to measure electrical current. If the architectures are implemented as another type of sensor, such as a position sensor, they may use only one sensing element. For instance, one of sensing elements 310 and 314 and one of trans-conductors 316 and 318 may be omitted from sensor 300 in some implementations. Similarly, one of sensing elements 408 and 412 and one of trans-conductors 414 and 422 may be omitted from sensor 400 in some implementations.

FIGS. 1A-4 are provided as an example only. Those of ordinary skill in the art will readily recognize that various modifications can be made to the examples shown in FIGS. 1A-4. The calibration coils in any of the examples of FIGS. 1A-4 can be connected in series or parallel: series coils reduce overall current consumption (a single current leg can generate a magnetic field at multiple hall plates) but require more voltage supply headroom. It is advantageous to connect as many coils as possible in series while maintaining sufficient voltage source headroom before adding coils in parallel and increasing current consumption. Any of the architectures shown in FIGS. 1A-4 may or may not perform frequency chopping on its Hall plates. Any of the architectures shown in FIGS. 1A-4 can use a notch filter to reduce the offset-induced ripple that appears as a result of the frequency chopping. Any of the architectures shown in FIGS. 1A-D may modulate the coil current (i.e., the signal used to drive the calibration coils) based on a Pseudo-Random Bit String (PRBS) signal or a fixed frequency signal. Any of the architecture shown in FIGS. 2-4 may modulate the coil current (i.e., the signal used to drive its calibration coils) based on a fixed-frequency signal rather than a PRBS signal. However, the frequency of the fixed-frequency signal should be higher than the frequency of a primary magnetic field that is being measured. Any of the architecture shown in FIGS. 2-4 can be used to implement another type of magnetic field sensor, such as a position sensor, and can be used to measure a magnetic field that is originating from a source other than a primary conductor, such as conductors 201, 301, and 401. The term “primary magnetic field” refers to any magnetic field of interest that is desired to be measured by a sensor, and its meaning is not limited to a magnetic field generated as a result of electrical current flowing through a conductor. The term “calibration magnetic field” refers to any magnetic field that is used to negate the effects of aging and environmental conditions on the sensing elements of the above-described sensors. Although, in the example of FIGS. 1A-4, the calibration coils are configured to surround the Hall elements they are intended to influence, in alternative implementations they may have a different relative positioning. The trans-conductors are used in each of the examples of FIGS. 1A-4 are Gibert cells. However, the present disclosure is not limited to using any specific type of trans-conductor. The substrates 171, 271, 371, and 471 which are used in the examples of FIGS. 1A-4 are silicon substrates. However, the present disclosure is not limited to any specific type of substrate being used. The calibration coils discussed with respect to FIGS. 1A-4 may be implemented by using conductive traces that are formed on the substrates. The term summation element may refer to digital and/or analog circuitry that is configured to perform a summation operation, such as addition or subtraction. In some implementations, the circuitry may implement hard logic for performing a summation operation or programmable logic that is programmed to perform the summation operation.

FIGS. 1A-4 are provided as an example only. Throughout the disclosure, like reference numerals refer to like parts. The examples provided with respect to FIGS. 1A-4 are not mutually exclusive and may be combined, modified, or adapted in various ways by those skilled in the art without departing from the scope and spirit of the invention defined by the appended claims. period.

Although the architectures shown in FIGS. 1A-4 use Hall elements (e.g., either vertical or planar Hall elements), in alternative implementations they can use a different type of magnetic field sensing element, such as a GMR, AMR, TMR, MTJ and/or any other suitable type of magnetic-field sensing element. A magnetic-field sensing element can be, but is not limited to, a Hall Effect element a magnetoresistance element, or an inductive coil. As is known, there are different types of Hall Effect elements, for example, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb). The phrase “set of magnetic field elements” shall mean “one or more magnetic field sensing elements”.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special-purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., an addition unit, a multiplication unit, etc.), as used throughout the disclosure may refer to hardware (e.g., an electronic circuit) that is configured to perform a function (e.g., addition or multiplication, etc.), software that is executed by at least one processor, and configured to perform the function, or a combination of hardware and software.

Also, for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements. Like reference numerals refer to like elements.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A sensor, comprising:
a first sensing element and a first calibration coil that is disposed adjacent to the first sensing element, the first sensing element being configured to generate a first signal at least in response to a primary magnetic field and a first calibration magnetic field that is generated by the first calibration coil;
a second sensing element and a second calibration coil that is disposed adjacent to the second sensing element, the second sensing element being configured to generate a second signal at least in response to the primary magnetic field and a second calibration magnetic field that is generated by the second calibration coil; and
one or more first summation elements that are configured to: (i) generate a calibration signal based on a difference between the first signal and the second signal by subtracting the difference from a reference signal and (ii) adjust respective biases of the first sensing element and the second sensing element based on the calibration signal,
wherein the first calibration magnetic field and the second calibration magnetic field have opposite directions,
wherein the primary magnetic field has a same direction at respective locations of the first sensing element and the second sensing element, and
wherein adjusting the biases of the first sensing element and the second sensing element causes respective outputs of the first sensing element and the second sensing element to have a first gain that matches a second gain of the reference signal.

2. The sensor of claim 1, wherein the reference signal is generated by electronic circuitry that is more stable than the first and second sensing elements such that a level of the reference signal varies less in response to aging or environmental conditions than sensitivities of the first and second sensing elements.

3. The sensor of claim 1, wherein the first signal, the second signal, and reference signal are current signals.

4. The sensor of claim 1, wherein the first sensing element includes a first Hall element and the second sensing element includes a second Hall element.

5. The sensor of claim 1, further comprising a conductor and a third summation element that is configured to add the first signal to the second signal to produce a third signal, the third signal being indicative of a level of electrical current through the conductor.

6. The sensor of claim 1, further comprising:
a conductor;
a third sensing element and a third calibration coil that is disposed adjacent to the third sensing element, the third sensing element being configured to generate a third signal at least in response to the primary magnetic field and a third calibration magnetic field that is generated by the third calibration coil; and
a fourth sensing element and a fourth calibration coil that is disposed adjacent to the fourth sensing element, the fourth sensing element being configured to generate a fourth signal at least in response to the primary magnetic field and a fourth calibration magnetic field that is generated by the fourth calibration coil,
wherein the first summation elements are configured to: add the difference between the first signal and the second signal to a difference between the third signal and the fourth signal, such that the calibration signal is generated by subtracting the resulting sum from the reference signal, and
wherein the first and second sensing elements are disposed on a first side of the conductor and the third and fourth sensing elements are disposed on a second side of the conductor.

7. A sensor, comprising:
a first sensing element and a first calibration coil that is disposed adjacent to the first sensing element, the first sensing element being configured to generate a first signal at least in response to a primary magnetic field and a first calibration magnetic field that is generated by the first calibration coil;
a second sensing element and a second calibration coil that is disposed adjacent to the second sensing element, the second sensing element being configured to generate a second signal at least in response to the primary magnetic field and a second calibration magnetic field that is generated by the second calibration coil;
a first modulator that is configured to modulate a signal used to drive the first calibration coil and the second calibration coil based on a signal M;
a first summation element that is configured to add the second signal to the first signal to at least in part generate a third signal that is indicative of a sum of the first signal and the second signal; and
a feedback circuit that is configured to execute a correlation function that correlates the signal M with the signal used to drive the first calibration coil and adjust a bias of the first sensing element and the second sensing element based on a value of the correlation function,
wherein the first calibration magnetic field and the second calibration magnetic field have a same direction, and
wherein the primary magnetic field has opposite directions at respective locations of the first sensing element and the second sensing element.

8. The sensor of claim 7, wherein the signal M includes a pseudo-random bit string signal (PRBS).

9. The sensor of claim 7, wherein the signal M includes a constant frequency signal.

10. The sensor of claim 7, wherein the first and second signal are modulated at a chopping frequency, and the third signal is generated by demodulating the sum of the first signal and the second signal based on the chopping frequency.

11. The sensor of claim 7, further comprising:
a first trans-conductor that is configured to generate the first signal based on an output of the first sensing element; and
a second trans-conductor that is configured to generate the second signal based on an output of the second sensing element.

12. The sensor of claim 7, wherein the feedback circuit includes:
a first multiplier that is configured to demodulate the third signal based on the second instance of the signal M to produce a demodulated third signal;
a second summation element that is configured to subtract the demodulated third signal from a predetermined reference signal to produce a difference signal;
a second multiplier that is configured to multiply the difference signal by a set of coefficients to produce a product signal; and
an integrator that is configured to integrate the product signal to produce a calibration signal that is indicative of the value of the correlation function, the correlation function being implemented by using the first and second multipliers, the summation element, and the integrator.

13. The sensor of claim 7, further comprising a conductor and a second summation element that is configured to subtract the second signal from the first signal to produce a third signal, the third signal being indicative of a level of electrical current through the conductor.

14. A sensor, comprising:
a first sensing element and a first calibration coil that is disposed adjacent to the first sensing element, the first sensing element being configured to generate a first signal at least in response to a primary magnetic field and a first calibration magnetic field that is generated by the first calibration coil;
a second sensing element and a second calibration coil that is disposed adjacent to the second sensing element, the second sensing element being configured to generate a second signal at least in response to the primary magnetic field and a second calibration magnetic field that is generated by the second calibration coil;
a first modulator that is configured to modulate a signal used to drive the first calibration coil and the second calibration coil based on a signal M;
a first summation element that is configured to subtract the second signal from the first signal to at least in part generate a third signal, the third signal being indicative of a difference between the first signal and the second signal; and
a feedback circuit that is configured to execute a correlation function that correlates the signal M with the signal used to drive the first calibration coil and adjust a gain of the first signal and the second signal based on a value of the correlation function,
wherein the first calibration magnetic field and the second calibration magnetic field have different directions, and
wherein the primary magnetic field has opposite directions at respective locations of the first sensing element and the second sensing element.

15. The sensor of claim 14, wherein the third signal is generated by subtracting the signal M from the difference between the first signal and the second signal.

16. The sensor of claim 14, wherein the primary magnetic field is generated as a result of electrical current flowing through a conductor.

17. The sensor of claim 14, wherein:
the first sensing element includes a first Hall element and the second sensing element includes a second Hall element;
wherein the primary magnetic field is generated by electrical current flowing through a conductor; and
the third signal is indicative of a level of the electrical current.

18. The sensor of claim 14, further comprising:
a first trans-conductor that is configured to generate the first signal based on an output of the first sensing element; and
a second trans-conductor that is configured to generate the second signal based on an output of the second sensing element.

19. The sensor of claim 14, wherein the feedback circuit includes:
a first multiplier that is configured to demodulate the third signal based on the signal M to produce a demodulated third signal;
a second summation element that is configured to subtract the demodulated third signal from a predetermined reference signal to produce a difference signal;
a second multiplier that is configured to multiply the difference signal by a set of coefficients to produce a product signal; and
an integrator that is configured to integrate the difference signal to produce a calibration signal that is indicative of the value of the correlation function, the correlation function being implemented by using the first and second multipliers, the summation element, and the integrator.

20. The sensor of claim 14, wherein the feedback circuit includes:
a first multiplier that is configured to demodulate the third signal based on the signal M to produce a demodulated third signal;
a second multiplier that is configured to multiply the demodulated third signal by a set of coefficients to produce a product signal; and
an integrator that is configured to integrate the product signal to produce a calibration signal that is indicative of the value of the correlation function, the correlation function being implemented by using the integrator and the second modulator.
